(19) United States
(12) Patent Application Publication
(10) Pub. No.: US 2024/0337525 A1
(43) Pub. Date: Oct. 10, 2024

(54) Method and System for Correcting Imbalance in In-phase/Quadrature Demodulation of Optical fiber DAS Data

(71) Applicant: China National Petroleum Corporation, Beijing (CN)

(72) Inventors: Yanpeng LI, Hebei (CN); Shaohua ZHANG, Hebei (CN); Fei LI, Hebei (CN)

(73) Assignee: China National Petroleum Corporation, Beijing (CN)

(21) Appl. No.: 18/576,554

(22) PCT Filed: Jun. 30, 2022
(86) PCT No.: PCT/CN2022/102882

§ 371 Date: Jan. 4, 2024

(30) Foreign Application Priority Data
Dec. 30, 2021 (CN) 202111645744.5

(51) Int. Cl. G01H 9/00; G01V 1/36

(52) U.S. Cl. CPC G01H 9/004; G01V 1/36; G01V 2210/30

(57) ABSTRACT

A method for correcting imbalance in IQ demodulation of optical fiber DAS data is disclosed. The method includes obtaining I/Q signals I0 and Q0 of each sampling on an optical fiber from a DAS acquisition instrument; performing DC bias correction on the I/Q signals I0 and Q0 to obtain I/Q signals I1 and Q1 after DC bias correction; performing amplitude imbalance correction on the I/Q signals I1 and Q1 after DC bias correction by using Hilbert transform to obtain I/Q signals I2 and Q2 after amplitude imbalance correction; and performing phase imbalance correction on the I/Q signals I2 and Q2 after amplitude imbalance correction by using Hilbert transform to obtain I/Q signals I3 and Q3 after phase imbalance correction. It is possible to perform accurate correction on I/Q signals, accurately and efficiently suppress optical fiber demodulation noise, and improve optical fiber DAS data acquisition quality.

### FIELD OF THE INVENTION

The present invention relates to the technical field of optical fiber sensing and seismic exploration, and particularly relates to a method and system for correcting imbalance in In-phase/Quadrature (I/Q, or IQ) demodulation of optical fiber DAS data.

### BACKGROUND OF THE INVENTION

The optical fiber Distributed Acoustic Sensing (DAS) technology is a revolutionary new technology in which optical fiber is used as both a sensing medium and a transmission medium, and may sense acoustic vibration information around the optical fiber, and the acoustic vibration information is recorded by high-density time and space sampling. The DAS technology is widely applied in seismic data acquisition in wells, dam safety monitoring, perimeter security, pipe monitoring or other aspects. The DAS technology mainly utilizes Rayleigh backscattering (RBS) of laser when laser propagates through the optical fiber. RBS changes accordingly when a medium surrounding the optical fiber vibrates. Seismic wave information of the formation may be obtained by continuously observing and demodulating this optical signal.

The DAS technology generally employs a phase-sensitive Optical Time Domain Reflectometer (φ-OTDR) to obtain RBS phase information by In-phase/Quadrature (I/Q, or IQ) phase demodulation. Due to the inherent errors of an optical fiber sensing device, such as direct current (DC) bias, amplitude imbalance and phase imbalance, output I/Q values vary elliptically on a crossplot, and a demodulation phase exhibits a non-linear relationship with a to-be-measured physical quantity, so that the phase demodulation accuracy is seriously affected, and the phase noise generated thereby is difficult to remove in subsequent signal processing. Therefore, how to achieve high-accuracy DAS phase demodulation becomes an important and difficult task constraining the development of this technology, and many experts at home and abroad work on eliminating such complex interference.

### SUMMARY OF THE INVENTION

The present invention provides a method and system for correcting imbalance in IQ demodulation of optical fiber DAS data for the technical problem in the prior art that phase noise is difficult to remove in signal processing. The method is employed to be capable of correcting I/Q signals accurately, suppressing optical fiber demodulation noise accurately and efficiently, and improving optical fiber DAS data acquisition quality.

To achieve the above objective, the present invention, in a first aspect, provides a method for correcting imbalance in IQ demodulation of optical fiber DAS data, including the following steps: obtaining I/Q signals I₀ and Q₀ of each sampling on an optical fiber; performing DC bias correction on the I/Q signals I₀ and Q₀ to obtain I/Q signals I₁ and Q₁ after DC bias correction; performing amplitude imbalance correction on the I/Q signals I₁ and Q₁ after DC bias correction by using Hilbert transform to obtain I/Q signals I₂ and Q₂ after amplitude imbalance correction; and performing phase imbalance correction on the I/Q signals I₂ and Q₂ after amplitude imbalance correction by using Hilbert transform to obtain I/Q signals I₃ and Q₃ after phase imbalance correction.

Optionally, wherein the step of performing DC bias correction on the I/Q signals I₀ and Q₀ to obtain I/Q signals I₁ and Q₁ after DC bias correction comprises: calculating corresponding DC bias factors Dᵢ and D_{q} according to the I/Q signals I₀ and Q₀; and performing DC bias correction on the I/Q signals I₀ and Q₀ by using the DC bias factors Dᵢ and D_{q} to obtain the I/Q signals I₁ and Q₁ after DC bias correction.

Optionally, wherein the step of calculating corresponding DC bias factors Dᵢ and D_{q} according to the I/Q signals I₀ and Q₀ comprises: calculating the corresponding DC bias factors Dᵢ and D_{q} according to a mean value of the I/Q signals I₀ and Q₀ at different time.

Optionally, wherein the step of performing amplitude imbalance correction on the I/Q signals I₁ and Q₁ after DC bias correction by using Hilbert transform to obtain I/Q signals I₂ and Q₂ after amplitude imbalance correction comprises: calculating corresponding amplitude imbalance factors Aᵢ and A_{q} by using Hilbert transform and the I/Q signals I₁ and Q₁ after DC bias correction; and performing amplitude imbalance correction on the I/Q signals I₁ and Q₁ after DC bias correction according to the amplitude imbalance factors Aᵢ and A_{q} to obtain the I/Q signals I₂ and Q₂ after amplitude imbalance correction.

Optionally, wherein the step of calculating corresponding amplitude imbalance factors Aᵢ and A_{q} by using Hilbert transform and the I/Q signals I₁ and Q₁ after DC bias correction comprises: calculating corresponding instantaneous amplitudes of the I/Q signals I₁ and Q₁ by Hilbert transform; and calculating the corresponding amplitude imbalance factors Aᵢ and A_{q} according to a mean value of corresponding instantaneous amplitudes at different time.

Optionally, wherein the step of performing phase imbalance correction on the I/Q signals I₂ and Q₂ after amplitude imbalance correction by using Hilbert transform to obtain I/Q signals I₃ and Q₃ after phase imbalance correction comprises: calculating phases ψᵢ and ψ_{q} corresponding to the I/Q signals I₂ and Q₂ by using Hilbert transform and the I/Q signals I₂ and Q₂ after amplitude imbalance correction; calculating a phase imbalance factor θ according to the phases ψᵢ and ψ_{q} corresponding to the I/Q signals I₂ and Q₂; and performing phase imbalance correction on the I/Q signals I₂ and Q₂ after amplitude imbalance correction according to the phase imbalance factor θ to obtain the I/Q signals I₃ and Q₃ after phase imbalance correction.

Optionally, wherein the step of calculating phases ψᵢ and ψ_{q} corresponding to the I/Q signals I₂ and Q₂ by using Hilbert transform and the I/Q signals 1₂ and Q₂ after amplitude imbalance correction comprises: obtaining the corresponding phases ψᵢ and ψ_{q} by an arctangent function of a ratio of the I/Q signals I₂ and Q₂ to the corresponding I/Q signals after Hilbert transform.

Optionally, wherein the step of calculating a phase imbalance factor θ according to the phases ψᵢ and ψ_{q} corresponding to the I/Q signals comprises: determining the phase imbalance factor θ by using a mean value of differences of the phases ψᵢ and ψ_{q} at different time.

Optionally, wherein performing phase imbalance correction on the I/Q signals I₂ and Q₂ after amplitude imbalance correction according to the phase imbalance factor θ by the following manner to obtain the I/Q signals I₃ and Q₃ after phase imbalance correction:

$$\begin{matrix}{I}_{3} = {I}_{2} ; \\ {Q}_{3} = \frac{{Q}_{2} - {I}_{2} sin θ}{cos θ} .\end{matrix}$$

The present invention, in a second aspect, provides a system for correcting imbalance in IQ demodulation of optical fiber DAS data, which is characterized by including: an obtaining module, configured to obtain I/Q signals I₀ and Q₀ of each sampling on an optical fiber; a DC bias correction module, configured to perform DC bias correction on the I/Q signals I₀ and Q₀ to obtain I/Q signals I₁ and Q₁ after DC bias correction; an amplitude imbalance correction module, configured to perform amplitude imbalance correction on the I/Q signals I₁ and Q₁ after DC bias correction by using Hilbert transform to obtain I/Q signals I₂ and Q₂ after amplitude imbalance correction; a phase imbalance correction module, configured to perform phase imbalance correction on the I/Q signals I₂ and Q₂ after amplitude imbalance correction by using Hilbert transform to obtain I/Q signals I₃ and Q₃ after phase imbalance correction.

The present invention has at least the following technical effects by the technical solutions provided by the present invention:

According to the method for correcting imbalance in IQ demodulation of optical fiber DAS data, the I/Q signals I₀ and Q₀ of each sampling (i.e., observation point) on the optical fiber are obtained; DC bias correction is performed on the I/Q signals I₀ and Q₀ to obtain I/Q signals I₁ and Q₁ after DC bias correction; then, amplitude imbalance correction is performed on the I/Q signals I₁ and Q₁ after DC bias correction by using Hilbert transform to obtain I/Q signals I₂ and Q₂ after amplitude imbalance correction; and subsequently, phase imbalance correction is performed on the I/Q signals I₂ and Q₂ after amplitude imbalance correction by using Hilbert transform to obtain I/Q signals I₃ and Q₃ after phase imbalance correction. It is possible to perform accurate correction on I/Q signals, accurately and efficiently suppress optical fiber demodulation noise, and improve optical fiber DAS data acquisition quality by the method provided by the present invention.

Other features and advantages of the present invention will be described in detail in the detailed description of the embodiments below.

### BRIEF DESCRIPTION OF DRAWINGS

The drawings are used to provide a further understanding of embodiments of the present invention and constitute a part of this specification, and to explain the embodiments of the present invention together with specific implementation modes, but do not limit the embodiments of the present invention. In the drawings:

FIG. 1 is a flowchart illustrating a method for correcting imbalance in IQ demodulation of optical fiber DAS data according to an embodiment of the present invention;

FIG. 2 is a schematic diagram illustrating I/Q signals I₀(tᵢ) and Q₀(tᵢ) at sample points when there is no external acoustic signal in a method for correcting imbalance in IQ demodulation of optical fiber DAS data according to an embodiment of the present invention;

FIG. 3 is a schematic diagram illustrating I/Q signals I₁(tᵢ) and Q₁(tᵢ) after DC bias correction in a method for correcting imbalance in IQ demodulation of optical fiber DAS data according to an embodiment of the present invention;

FIG. 4 is a schematic diagram illustrating I/Q signals I₂(tᵢ) and Q₂(tᵢ) after amplitude imbalance correction in a method for correcting imbalance in IQ demodulation of optical fiber DAS data according to an embodiment of the present invention;

FIG. 5 is a schematic diagram illustrating a phase curve and a phase difference curve of I/Q signals obtained by Hilbert transform in a method for correcting imbalance in IQ demodulation of optical fiber DAS data according to an embodiment of the present invention;

FIG. 6 is a schematic diagram illustrating I/Q signals I₃(tᵢ) and Q₃(tᵢ) after imbalance correction in a method for correcting imbalance in IQ demodulation of optical fiber DAS data according to an embodiment of the present invention;

FIG. 7 is a zoomed view illustrating I/Q signals I₂(tᵢ) and Q₂(tᵢ) after amplitude imbalance correction in a method for correcting imbalance in IQ demodulation of optical fiber DAS data according to an embodiment of the present invention;

FIG. 8 is a partially enlarged view illustrating I/Q signals I₃(tᵢ) and Q₃(tᵢ) after phase imbalance correction in a method for correcting imbalance in IQ demodulation of optical fiber DAS data according to an embodiment of the present invention;

FIG. 9 is a schematic diagram illustrating a demodulation phase curve and a demodulation phase difference curve before and after imbalance correction in a method for correcting imbalance in IQ demodulation of optical fiber DAS data according to an embodiment of the present invention;

FIG. 10 is a schematic diagram illustrating amplitude curves before and after imbalance correction in a method for correcting imbalance in IQ demodulation of optical fiber DAS data according to an embodiment of the present invention;

FIG. 11 is a schematic diagram illustrating I/Q cross plots before and after imbalance correction in a method for correcting imbalance in IQ demodulation of optical fiber DAS data according to an embodiment of the present invention;

FIG. 12 is a schematic diagram illustrating IQ demodulation background noise before and after imbalance correction in a method for correcting imbalance in IQ demodulation of optical fiber DAS data according to an embodiment of the present invention;

FIG. 13 is a schematic diagram illustrating IQ demodulation seismic wavefields before and after imbalance correction in a method for correcting imbalance in IQ demodulation of optical fiber DAS data according to an embodiment of the present invention; and

FIG. 14 is a schematic diagram illustrating a system for correcting imbalance in IQ demodulation of optical fiber DAS data according to an embodiment of the present invention.

### DETAILED DESCRIPTION OF THE EMBODIMENTS

The specific implementation modes of the embodiments of the present invention are described in detail below in combination with the drawings. It should be understood that the specific implementation modes described herein are only used for describing and explaining the embodiments of the present invention and are not used for limiting the embodiments of the present invention.

The obtainment, storage, use, processing, or the like of data in the technical solutions of the present application comply with the relevant provisions of national laws and regulations.

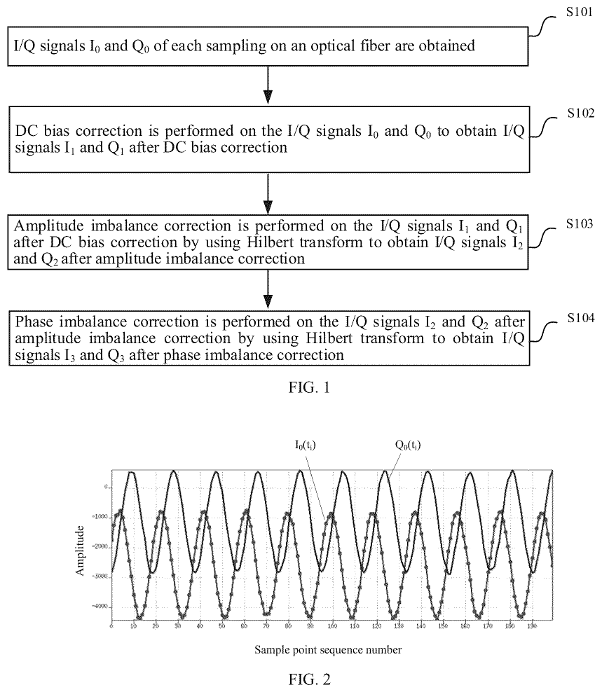

Referring to FIG. 1, the present invention, in a first aspect, provides a method for correcting imbalance in IQ demodulation of optical fiber DAS data, including the following steps.

S101: I/Q signals I₀ and Q₀ of each sampling on an optical fiber are obtained.

Specifically, in an embodiment of the present invention, an optical fiber DAS acquisition instrument is connected to an optical fiber coupled to a to-be-measured object, and I/Q signals I₀ and Q₀ are output at each sampling on the optical fiber in the absence of external acoustic signals around the optical fiber in the case of emitting optical pulses at a certain frequency. The optical fiber DAS acquisition instrument is an instrument with a phase-sensitive optical time domain reflectometer (φ-OTDR) as a core. The I/Q signals are in-phase and quadrature signals, and it is assumed that there is no external acoustic signals near each sampling on the optical fiber.

S102: DC bias correction is performed on the I/Q signals I₀ and Q₀ to obtain I/Q signals I₁ and Q₁ after DC bias correction.

Further, the step that DC bias correction is performed on the I/Q signals I₀ and Q₀ to obtain I/Q signals I₁ and Q₁ after DC bias correction includes the following step: Corresponding DC bias factors Dᵢ and D_{q} are calculated according to a mean value of the I/Q signals I₀ and Q₀ at different time:

$$\begin{matrix}{D}_{i} = \frac{1}{n} {\sum }_{i = 1}^{n} {I}_{0} ( {t}_{i} ) ; \\ {D}_{q} = \frac{1}{n} {\sum }_{i = 1}^{n} {Q}_{0} ( {t}_{i} ) ;\end{matrix}$$

wherein I₀(tᵢ) and Q₀(tᵢ) are I/Q signals I₀ and Q₀ at time tᵢ, n is the number of samples for calculation.

DC bias correction is performed on the I/Q signals I₀ and Q₀ by using the DC bias factors Dᵢ and D_{q} to obtain the I/Q signals I₁ and Q₁ after DC bias correction:

$$\begin{matrix}{I}_{1} ( {t}_{i} ) = {I}_{0} ( {t}_{i} ) - {D}_{i} ; \\ {Q}_{1} ( {t}_{i} ) = {Q}_{0} ( {t}_{i} ) - {D}_{q} ;\end{matrix}$$

wherein I₁ (tᵢ) and Q₁ (tᵢ) are I/Q signals I₁ and Q₁ at time tᵢ.

S103: Amplitude imbalance correction is performed on the I/Q signals I₁ and Q₁ after DC bias correction by using Hilbert transform to obtain I/Q signals I₂ and Q₂ after amplitude imbalance correction.

Further, the step that amplitude imbalance correction is performed on the I/Q signals I₁ and Q₁ after DC bias correction by using Hilbert transform to obtain I/Q signals I₂ and Q₂ after amplitude imbalance correction includes the following steps: Corresponding instantaneous amplitudes of the I/Q signals I₁ and Q₁ are calculated by Hilbert transform; and Corresponding amplitude imbalance factors Aᵢ and A_{q} are calculated according to a mean value of corresponding instantaneous amplitudes at different time:

$${A}_{i} = \frac{1}{n} {\sum }_{i = 1}^{n} \sqrt{{I}_{1}^{2} ( {t}_{i} ) + {\tilde{I}}_{1}^{2} ( {t}_{i} )} ;$$

$${A}_{q} = \frac{1}{n} {\sum }_{i = 1}^{n} \sqrt{{Q}_{1}^{2} ( {t}_{i} ) + {\tilde{Q}}_{1}^{2} ( {t}_{i} )} ;$$

wherein [symbol] (tᵢ) and [symbol] (tᵢ) are I/Q signals obtained by Hilbert transform on the I/Q signals I₁(tᵢ) and Q₁(tᵢ) after DC bias correction, n is the number of samples for calculation.

Amplitude imbalance correction is performed on the I/Q signals I₁ and Q₁ after DC bias correction according to the amplitude imbalance factors Aᵢ and A_{q} to obtain the I/Q signals I₂ and Q₂ after amplitude imbalance correction:

$${I}_{2} \{ {t}_{i} ) = {I}_{1} ( {t}_{i} ) / {A}_{i} ;$$

$${Q}_{2} \{ {t}_{i} ) = {Q}_{1} ( {t}_{i} ) / {A}_{q} ;$$

wherein I₂(tᵢ) and Q₂(tᵢ) are I/Q signals I₂ and Q₂ at time tᵢ.

S104: Phase imbalance correction is performed on the I/Q signals I₂ and Q₂ after amplitude imbalance correction by using Hilbert transform to obtain I/Q signals I₃ and Q₃ after phase imbalance correction.

Further, the step that phase imbalance correction is performed on the I/Q signals I₂ and Q₂ after amplitude imbalance correction by using Hilbert transform to obtain I/Q signals I₃ and Q₃ after imbalance correction includes the following steps: Corresponding phases ψᵢ and ψ_{q} are obtained by an arctangent function of a ratio of the I/Q signals I₂ and Q₂ to the corresponding I/Q signals after Hilbert transform:

$${ψ}_{i} ( {t}_{i} ) = arctan ( \frac{\tilde{{I}_{2}} ( {t}_{i} )}{{I}_{2} ( {t}_{i} )} ) ;$$

$${ψ}_{q} ( {t}_{i} ) = arctan ( \frac{\tilde{{Q}_{2}} ( {t}_{i} )}{{Q}_{2} ( {t}_{i} )} ) ;$$

wherein [symbol] (tᵢ) and [symbol] (tᵢ) are I/Q signals obtained by Hilbert transform on the I/Q signals I₂(tᵢ) and Q₂(tᵢ) after amplitude imbalance correction.

A phase imbalance factor θ is determined by using a mean value of differences of the phases ψᵢ and ψ_{q} at different time:

$$θ = \frac{1}{n} {\sum }_{i = 1}^{n} ( {ψ}_{q} ( {t}_{i} ) - {ψ}_{i} ( {t}_{i} ) - \frac{π}{2} ) .$$

Phase imbalance correction is performed on the I/Q signals I₂(tᵢ) and Q₂(tᵢ) after amplitude imbalance correction according to the phase imbalance factor θ to obtain I/Q signals I₃(tᵢ) and Q₃(tᵢ) after imbalance correction:

$${I}_{3} ( {t}_{i} ) = {I}_{2} ( {t}_{i} ) ;$$

$${Q}_{3} ( {t}_{i} ) = \frac{{Q}_{2} ( {t}_{i} ) - {I}_{2} ( {t}_{i} ) sin θ}{cos θ} .$$

Then, subsequent phase demodulation and phase unwrapping may be performed by using the above data to obtain a demodulation phase ω and an amplitude Amp, thereby obtaining acoustic wavefield data. The demodulation phase ω and the amplitude Amp are calculated as follows:

$$ω ( {t}_{i} ) = arctan ( \frac{{Q}_{3} ( {t}_{i} )}{{I}_{3} ( {t}_{i} )} ) ;$$

$$Amp ( {t}_{i} ) = \sqrt{{I}_{3}^{2} ( {t}_{i} ) + {Q}_{3}^{2} ( {t}_{i} )} .$$

In an embodiment of the present invention, the DC bias factors Dᵢ and D_{q}, the amplitude imbalance factors Aᵢ and A_{q}, and the phase imbalance factor θ may be obtained by selecting positions without external acoustic signals uniformly after the I/Q signals I₀ and Q₀ at each sampling on the optical fiber are obtained, and then are applied to all acquired data at all samplings.

### Embodiment

A optical fiber DAS acquisition instrument is connected to an optical fiber hung in a cased well, in the case of emitting optical pulses at a repetition rate of 10 K, I/Q signals I₀(tᵢ) and Q₀(tᵢ) output at time tᵢ(i=1, 2, 3, . . . ) at each sampling on the optical fiber without external acoustic signals around the optical fiber are acquired when a vibroseis is not excited, as shown in FIG. 2.

Corresponding DC bias factors Dᵢ and D_{q} are calculated according to a mean value of the I/Q signals I₀(tᵢ) and Q₀(tᵢ) at multiple points:

$${D}_{i} = \frac{1}{n} {\sum }_{i = 1}^{n} {I}_{0} ( {t}_{i} ) ;$$

$${D}_{q} = \frac{1}{n} {\sum }_{i = 1}^{n} {Q}_{0} ( {t}_{i} ) ;$$

DC bias correction is performed on the I/Q signals I₀(tᵢ) and Q₀(tᵢ) by using the DC bias factors Dᵢ and D_{q} to obtain I/Q signals I₁(tᵢ) and Q₁(tᵢ) after DC bias correction, as shown in FIG. 3:

$${I}_{1} ( {t}_{i} ) = {I}_{0} ( {t}_{i} ) - {D}_{i} ;$$

$${Q}_{1} ( {t}_{i} ) = {Q}_{0} ( {t}_{i} ) - {D}_{q} .$$

Then, corresponding amplitude imbalance factors Aᵢ and A_{q} are calculated by using Hilbert transform and the I/Q signals I₁(t) and Q₁(t) after DC bias correction:

$${A}_{i} = \frac{1}{n} {\sum }_{i = 1}^{n} \sqrt{{I}_{1}^{2} ( {t}_{i} ) + {\tilde{I}}_{1}^{2} ( {t}_{i} )} ;$$

$${A}_{q} = \frac{1}{n} {\sum }_{i = 1}^{n} \sqrt{{Q}_{1}^{2} ( {t}_{i} ) + {\tilde{Q}}_{1}^{2} ( {t}_{i} )} ;$$

wherein [symbol] (tᵢ) and [symbol] (tᵢ) are I/Q signals obtained by Hilbert transform on the I/Q signals I₁(tᵢ) and Q₁(tᵢ) after DC bias correction.

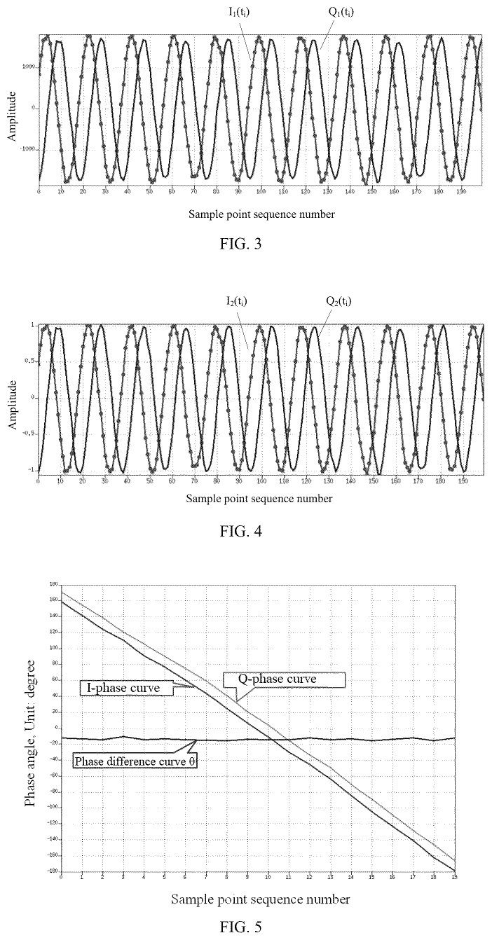

Amplitude imbalance correction is performed on the I/Q signals I₁(tᵢ) and Q₁(tᵢ) after DC bias correction according to the amplitude imbalance factors Aᵢ and A_{q} to obtain I/Q signals I₂(tᵢ) and Q₂(tᵢ) after amplitude imbalance correction, as shown in FIG. 4:

$${I}_{2} ( {t}_{i} ) = {I}_{1} ( {t}_{i} ) / {A}_{i} ;$$

$${Q}_{2} ( {t}_{i} ) = {Q}_{1} ( {t}_{i} ) / {A}_{q} .$$

Then, phases ψᵢ(tᵢ) and ψ_{q}(tᵢ) corresponding to the the I/Q signals I₂(tᵢ) and Q₂(tᵢ) are calculated by using Hilbert transform and the I/Q signals I₂(tᵢ) and Q₂(tᵢ) after amplitude imbalance correction, as shown in FIG. 5:

$${ψ}_{i} ( {t}_{i} ) = arctan ( \frac{\tilde{{I}_{2}} ( {t}_{i} )}{{I}_{2} ( {t}_{i} )} ) ;$$

$${ψ}_{q} ( {t}_{i} ) = arctan ( \frac{\tilde{{Q}_{2}} ( {t}_{i} )}{{Q}_{2} ( {t}_{i} )} ) ;$$

wherein, [symbol] (tᵢ) and [symbol] (tᵢ) are I/Q signals obtained by Hilbert transform on I/Q signals I₂(tᵢ) and Q₂(tᵢ) after amplitude imbalance correction.

Referring to FIG. 5, a phase imbalance factor is calculated according to the phases ψᵢ(tᵢ) and ψ_{q}(tᵢ) corresponding to the I/Q signals, and the I/Q signals themselves are quadrature signals, and have a phase difference

$$\frac{π}{2} ,$$

so that the phase imbalance factor (phase difference) θ is:

$$θ = \frac{1}{n} {\sum }_{i = 1}^{n} ( {ψ}_{q} ( {t}_{i} ) - {ψ}_{i} ( {t}_{i} ) - \frac{π}{2} ) .$$

In this embodiment, the mean value of the phase difference is −14 degrees.

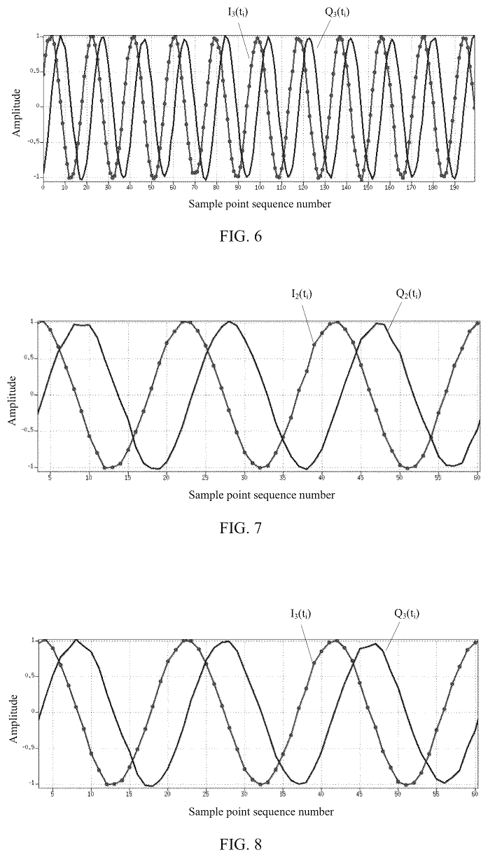

Phase imbalance correction is performed on the I/Q signals I₂(tᵢ) and Q₂(tᵢ) after amplitude imbalance correction according to the phase imbalance factor to obtain I/Q signals I₃(tᵢ) and Q₃(tᵢ) after imbalance correction, as shown in FIGS. 6-8, wherein FIG. 7 and FIG. 8 are zoomed views of the I/Q signals before and after phase imbalance correction:

$${I}_{3} ( {t}_{i} ) = {I}_{2} ( {t}_{i} ) ;$$

$${Q}_{3} ( {t}_{i} ) = \frac{{Q}_{2} ( {t}_{i} ) - {I}_{2} ( {t}_{i} ) sin θ}{cos θ} .$$

Subsequent phase demodulation and phase unwrapping may be performed by using the above data after the I/Q signals imbalance correction are obtained so as to obtain a demodulation phase ω and an amplitude Amp, thereby obtaining acoustic wavefield data. The demodulation phase ω and the amplitude Amp are calculated as follows:

$$ω ( {t}_{i} ) = arctan ( \frac{{Q}_{3} ( {t}_{i} )}{{I}_{3} ( {t}_{i} )} ) ;$$

$$Amp ( {t}_{i} ) = \sqrt{{I}_{3}^{2} ( {t}_{i} ) + {Q}_{3}^{2} ( {t}_{i} )} .$$

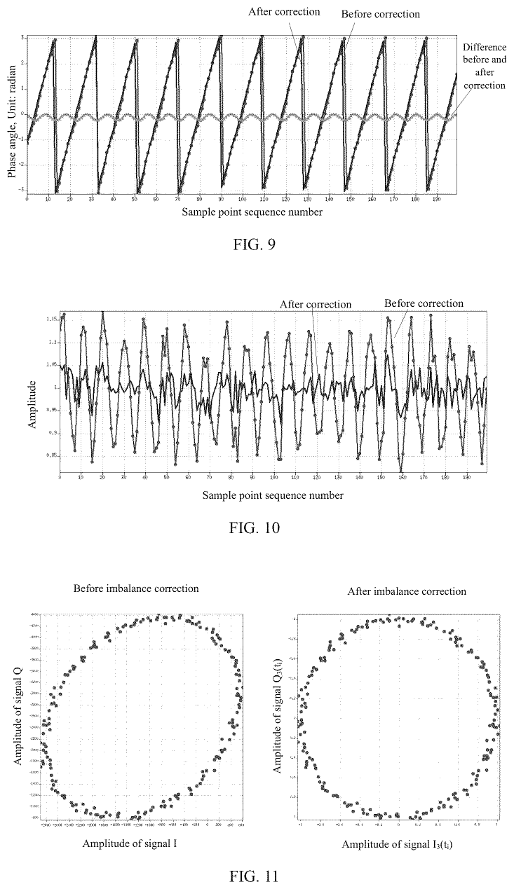

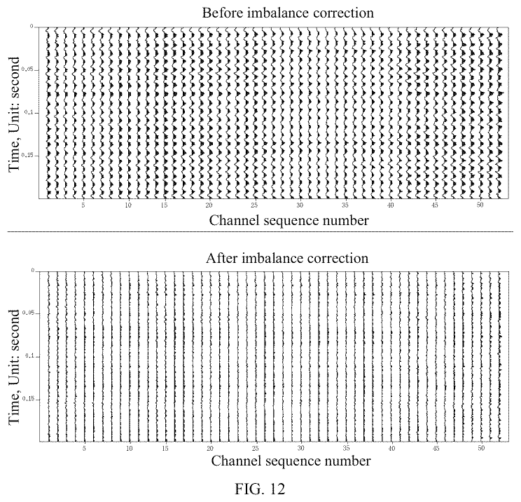

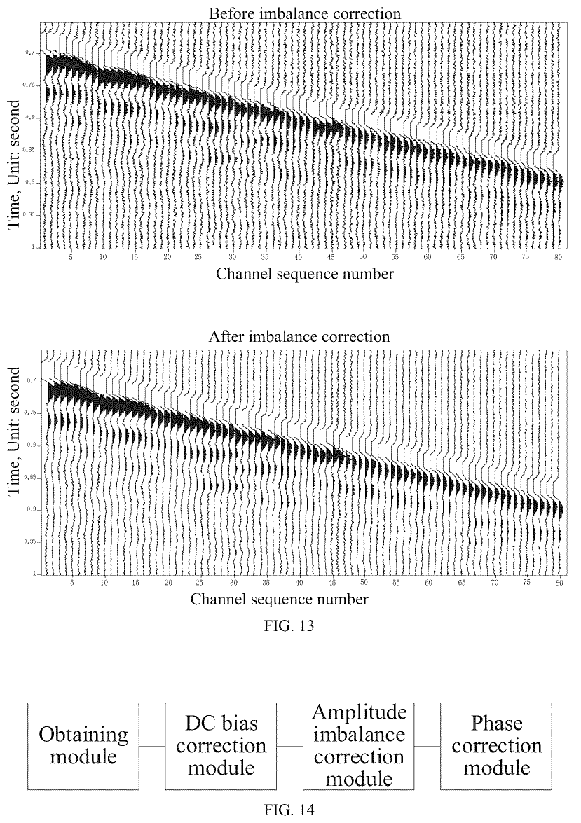

Referring to FIG. 9-FIG. 12, a demodulation phase curve and a demodulation phase difference curve before and after phase imbalance correction are as shown in FIG. 9. Amplitude curves before and after phase imbalance correction are as shown in FIG. 10. I/Q crossplots before and after imbalance correction are as shown in FIG. 11, and it can be seen that the crossplot is elliptical before correction and is circular after correction. IQ demodulation background noise before and after imbalance correction is as shown in FIG. 12, and the noise level is reduced by 60% or above by the method of the present invention. IQ demodulation seismic wavefields before and after imbalance correction are as shown in FIG. 13, and a signal-to-noise ratio is improved by 3-4 times by the method of the present invention.

Referring to FIG. 14, the present invention, in a second aspect, provides a system for correcting imbalance in IQ demodulation of optical fiber DAS data. The system includes: an obtaining module, configured to obtain I/Q signals I₀ and Q₀ of each sampling on an optical fiber; a DC bias correction module, configured to perform DC bias correction on the I/Q signals I₀ and Q₀ to obtain I/Q signals I₁ and Q₁ after DC bias correction; an amplitude imbalance correction module, configured to perform amplitude imbalance correction on the I/Q signals I₁ and Q₁ after DC bias correction by using Hilbert transform to obtain I/Q signals I₂ and Q₂ after amplitude imbalance correction; and a phase imbalance correction module, configured to perform phase imbalance correction on the I/Q signals I₂ and Q₂ after amplitude imbalance correction by using Hilbert transform to obtain I/Q signals I₃ and Q₃ after phase imbalance correction.

The preferred embodiments of the present invention are described above in detail in combination with the drawings, but the present invention is not limited to the specific details in the above embodiments. Various simple variations can be made to the technical solutions of the present invention in the scope of the technical concept of the present invention, and these simple variations all fall within the protection scope of the present invention.

In addition, it should be noted that the specific technical features described in the above specific embodiments can be combined in any appropriate mode under the non-contradictory condition, and various possible combination modes will not be described separately in order to avoid unnecessary repetition.

Furthermore, various different embodiments of the present invention can also be combined optionally, and the combinations also should be regarded as the content disclosed by the present invention as long as the combinations do not violate the concept of the present invention.

1. A method for correcting imbalance in IQ demodulation of optical fiber DAS data, comprising:
obtaining I/Q signals I₀ and Q₀ of each sampling;
performing DC bias correction on the I/Q signals Io and Q₀ to obtain I/Q signals I₁ and Q₁ after DC bias correction;
performing amplitude imbalance correction on the I/Q signals I₁ and Q₁ after DC bias correction by using Hilbert transform to obtain I/Q signals I₂ and Q₂ after amplitude imbalance correction; and
performing phase imbalance correction on the I/Q signals I₂ and Q₂ after amplitude imbalance correction by using Hilbert transform to obtain I/Q signals I₃ and Q₃ after phase imbalance correction.

2. The method according to claim 1, wherein the step of performing DC bias correction on the I/Q signals I₀ and Q₀ to obtain I/Q signals I₁ and Q₁ after DC bias correction comprises:
calculating corresponding DC bias factors Dᵢ and D_{q} according to the I/Q signals I₀ and Q₀; and
performing DC bias correction on the I/Q signals I₀ and Q₀ by using the DC bias factors Dᵢ and D_{q} to obtain the I/Q signals I₁ and Q₁ after DC bias correction.

3. The method according to claim 2, wherein the step of calculating corresponding DC bias factors Dᵢ and D_{q} according to the I/Q signals I₀ and Q₀ comprises:
calculating the corresponding DC bias factors Dᵢ and D_{q} according to a mean value of the I/Q signals I₀ and Q₀ at different time.

4. The method according to claim 1, wherein the step of performing amplitude imbalance correction on the I/Q signals I₁ and Q₁ after DC bias correction by using Hilbert transform to obtain I/Q signals I₂ and Q₂ after amplitude imbalance correction comprises:
calculating corresponding amplitude imbalance factors Aᵢ and A_{q} by using Hilbert transform and the I/Q signals I₁ and Q₁ after DC bias correction; and
performing amplitude imbalance correction on the I/Q signals I₁ and Q₁ after DC bias correction according to the amplitude imbalance factors Aᵢ and A_{q} to obtain the I/Q signals I₂ and Q₂ after amplitude imbalance correction.

5. The method according to claim 4, wherein the step of calculating corresponding amplitude imbalance factors Aᵢ and A_{q} by using Hilbert transform and the I/Q signals I₁ and Q₁ after DC bias correction comprises:
calculating corresponding instantaneous amplitudes of the I/Q signals I₁ and Q₁ by Hilbert transform; and
calculating the corresponding amplitude imbalance factors Aᵢ and A_{q} according to a mean value of corresponding instantaneous amplitudes at different time.

6. The method according to claim 1, wherein the step of performing phase imbalance correction on the I/Q signals I₂ and Q₂ after amplitude imbalance correction by using Hilbert transform to obtain I/Q signals I₃ and Q₃ after imbalance phase correction comprises:
calculating phases ψᵢ and ψ_{q} corresponding to the I/Q signals I₂ and Q₂ by using Hilbert transform and the I/Q signals I₂ and Q₂ after amplitude imbalance correction;
calculating a phase imbalance factor θ according to the phases ψᵢ and ψ_{q} corresponding to the I/Q signals I₂ and Q₂; and
performing phase imbalance correction on the I/Q signals I₂ and Q₂ after amplitude imbalance correction according to the phase imbalance factor θ to obtain the I/Q signals I₃ and Q₃ after phase imbalance correction.

7. The method according to claim 6, wherein the step of calculating phases ψᵢ and ψ_{q} corresponding to the I/Q signals I₂ and Q₂ by using Hilbert transform and the I/Q signals I₂ and Q₂ after amplitude imbalance correction comprises:
obtaining the corresponding phases ψᵢ and ψ_{q} by an arctangent function of a ratio of the I/Q signals I₂ and Q₂ to the corresponding I/Q signals after Hilbert transform.

8. The method according to claim 6, wherein the step of calculating a phase imbalance factor θ according to the phases ψᵢ and ψ_{q} corresponding to the I/Q signals comprises:
determining the phase imbalance factor θ by using a mean value of differences of the phases ψᵢ and ψ_{q} at different time.

9. The method according to claim 6, wherein performing phase imbalance correction on the I/Q signals I₂ and Q₂ after amplitude imbalance correction according to the phase imbalance factor θ by the following manner to obtain the I/Q signals I₃ and Q₃ after phase imbalance correction:
$${I}_{3} = {I}_{2} ;$$
$${Q}_{3} = \frac{{Q}_{2} - {I}_{2} sin θ}{cos θ} .$$

10. A system for correcting imbalance in IQ demodulation of optical fiber DAS data, comprising:
an obtaining module, configured to obtain I/Q signals I₀ and Q₀ of each sampling on an optical fiber;
a DC bias correction module, configured to perform DC bias correction on the I/Q signals I₀ and Q₀ to obtain I/Q signals I₁ and Q₁ after DC bias correction;
an amplitude imbalance correction module, configured to perform amplitude imbalance correction on the I/Q signals I₁ and Q₁ after DC bias correction by using Hilbert transform to obtain I/Q signals I₂ and Q₂ after amplitude imbalance correction; and
a phase imbalance correction module, configured to perform phase imbalance correction on the I/Q signals I₂ and Q₂ after amplitude imbalance correction by using Hilbert transform to obtain I/Q signals I₃ and Q₃ after phase imbalance correction.
